(19) United States
(12) Patent Application Publication
(10) Pub. No.: US 2026/0169106 A1
(43) Pub. Date: Jun. 18, 2026

(54) LOCAL COIL WITH ANALOG-DIGITAL CONVERTER, MIXER, OSCILLATOR, AND DECIMATOR

(71) Applicant: Siemens Healthineers AG, Forchheim (DE)

(72) Inventor: Jan Bollenbeck, Eggolsheim (DE)

(21) Appl. No.: 19/401,644

(22) Filed: Nov. 26, 2025

(30) Foreign Application Priority Data
Dec. 12, 2024 (EP) 24219415

(51) Int. Cl. G01R 33/36

(52) U.S. Cl. CPC G01R 33/3621

(57) ABSTRACT

The disclosure relates to a local coil for a magnetic resonance scanner with an analog-digital converter and a digital mixer, an oscillator, and a data rate decimator. The mixer and the oscillator are configured to downmix a digital magnetic resonance signal with an IQ oscillator signal in such a manner that the magnetic resonance signal at the output of the subsequent data rate decimator is converted into a real-valued low IF signal centered in a frequency range which corresponds either to the positive frequency subrange or to the negative frequency subrange of the baseband.

The present patent document claims the benefit of European Patent Application No. 24219415, filed Dec. 12, 2024, which is hereby incorporated by reference in its entirety.

### TECHNICAL FIELD

The disclosure relates to a local coil for a magnetic resonance tomography device and a magnetic resonance tomography device with a local coil. The local coil has an analog-to-digital converter.

### BACKGROUND

Magnetic resonance scanners are imaging apparatuses in which, to image an examination object, the nuclear spins of the examination object are aligned with a strong external magnetic field and excited to precess around this alignment by an alternating magnetic field. The precession or return of the spins from this excited state to a lower energy state in turn generates an alternating magnetic field in response, which is received via antennae.

With the aid of magnetic gradient fields, the signals are imprinted with a location code that subsequently enables assignment of the received signal to a volume element. The received signal is then evaluated and a three-dimensional image of the examination object is provided. Local receive antennae, so-called local coils, may be used to receive the signal. These are arranged directly on the examination object in order to achieve a better signal-to-noise ratio.

Increasingly, the aim is to digitize the received magnetic resonance signals already in the local coil, in particular in connection with wireless local coils, in order to reduce the data rates for transmission already in the local coil. However, digital signal processing with different switching times and the harmonic waves associated with the digital signal forms may cause additional interference signals in the patient tunnel.

### SUMMARY AND DESCRIPTION

It is therefore an object of the disclosure to improve a digital local coil.

The object is achieved by a local coil as described herein. The scope of the present disclosure is defined solely by the appended claims and is not affected to any degree by the statements within this summary. The present embodiments may obviate one or more of the drawbacks or limitations in the related art.

The local coil is configured for use with a magnetic resonance scanner in order to detect magnetic resonance signals with the highest possible signal-to-noise ratio and transmit them to the magnetic resonance scanner in digital form for evaluation and image generation.

The local coil has an analog-to-digital converter with which the detected magnetic resonance signal is digitized. The magnetic resonance signal may be recorded with one or more induction or antenna coils. The local coils in the analog signal path up to the analog-to-digital converter may also have elements for impedance matching and an amplifier. It is also conceivable that conversion is first carried out by analog mixers and/or filtering e.g., by bandpass filters.

The local coil also has a digital mixer, an oscillator, and a Digital Down Converter (DDC). A digital mixer or oscillator is understood to be a digital signal processing circuit or program for execution on a digital processor that, unlike an analog mixer or oscillator, performs operations on the signals such as multiplication or addition, by arithmetic operations on digital data or data streams. The digital mixer may be a semi-complex mixer and the oscillator may be an IQ (in-phase/quadrature) oscillator.

The digital mixer and the digital oscillator are configured to downmix a digital magnetic resonance signal with an IQ oscillator signal in such a manner that the magnetic resonance signal with both sidebands is converted centrally into a frequency range that corresponds to one of the first two Nyquist bands (positive or negative frequency) at the output of the following DDC. In other words, after conversion the magnetic resonance signal with both sides is located either above or below the 0 Hz line in the spectrum.

Downmixing may be performed, for example, by multiplying the digitized magnetic resonance signal by the digital IQ oscillator signal.

The oscillator may also be configured to generate the oscillator signal as a function of a reference signal supplied to the local coil from outside with a predetermined frequency, for example, from a reference signal supplied by the magnetic resonance scanner. It is also conceivable that the oscillator derives the mixed signal from the reference signal supplied from the outside, for example, by frequency division, frequency multiplication, or a phase-lock loop circuit. In principle, autonomous generation by the oscillator is conceivable if a sufficiently stable reference frequency is available.

The oscillator is configured to generate the oscillator signal for mixing in such a manner that the center frequency of the downmixed magnetic resonance signal may be converted centrally into a frequency range that corresponds either to the positive frequency subrange or the negative frequency subrange of the baseband at the output of the subsequent data rate decimator. The baseband extends symmetrically to the zero frequency point, the downmixed magnetic resonance signal, and its center frequency lying either above the zero point in the positive frequency range of the baseband or below the zero point in the negative frequency range of the baseband. In other words, after downmixing by the mixer, a signal that corresponds to the center frequency of the magnetic resonance signal is present at a frequency that deviates from F_{BW} of the half Nyquist frequency of the DDC output signal by less than 10%, 5%, or 1%. The center frequency corresponds to the Larmor frequency of the spins in the examination area to be recorded and may also be regarded as the carrier frequency of the nuclear spin signals modulated by the sequence.

The central frequency range in one of the first two Nyquist bands of the DDC output clocking advantageously provides an equal or symmetrical distance to the upper and lower limit of the frequency range, which simplifies the dimensioning of the filters for subsequent signal processing.

In one conceivable embodiment of the local coil, the oscillator is configured to generate the oscillator signal in such a manner that it lies outside the frequency range of the sampled MR signal. This also means that, even after downmixing, the oscillator signal itself or signals derived from processing in the local coil, such as harmonics or frequency multiples of the oscillator signal, are mapped to frequencies outside the frequency range of the sampled MR signal. The frequency of the oscillator signal is set accordingly so that, in conjunction with the mixing and signal processing acts in the local coil, a frequency scheme is applied in which the magnetic resonance signal downmixed by the mixer lies in the frequency space between signals or frequencies derived from the oscillator signal that, for example, arise as a result of mixing, decimation, or other non-linear processing acts from the oscillator signal. Signals may also be converted to the frequency range of the magnetic resonance signal by oversampling or undersampling.

Advantageously, this frequency scheme, which differs from the customary method used in IQ mixers in which downmixing to the baseband takes place with the center frequency at 0 Hz, provides that coupling of the oscillator signal into the analog-to-digital converter does not lead to image artifacts.

In one embodiment of the local coil, the analog-to-digital converter and the DDC are monolithic in design. Monolithic is understood to mean that both functions are integrated in one component, e.g., a silicon die or a module of the local coil. In particular, the functions or the modules performing the functions are not galvanically isolated from one another.

Advantageously, the integrated design allows for a cost-effective and energy-saving design, the frequency scheme providing that the oscillator signal does not result in interference in the reconstructed image due to scarcely avoidable coupling within the component.

In one conceivable embodiment of the local coil, the local coil has a wireless transmission apparatus. The local coil is designed to transmit the downmixed digital magnetic resonance signal wirelessly to a magnetic resonance scanner.

The downmixed signal allows bandwidth-efficient transmission of the digitized magnetic resonance signal, the energy-saving integrated design additionally allowing a longer operating life without recharging a battery.

In the system including a magnetic resonance system and a local coil, the local coil is configured to receive a reference signal from the magnetic resonance scanner via a signal connection. For example, the local coil may have a signal input for optical or electrical wired or wireless transmission. The oscillator is configured to generate a mixing frequency for the mixer as a function of a reference signal so that, as already explained, the magnetic resonance signal with both sidebands is positioned centrally in the frequency range of the DDC output signal. To this end, it is conceivable that the oscillator converts the oscillator signal by frequency division, multiplication, or PLL.

The system shares the advantages of the local coil as described herein.

In one conceivable embodiment of the method, the system has a signal processing chain for magnetic resonance signals. A signal processing chain refers to a sequence of analog and/or digital signal processing acts, which are recorded between recording of the magnetic resonance signal from the patient by antennae, (e.g., induction coils), and image reconstruction, (e.g., by FFT or AI). In particular, the signal chain concerns acts from a group of amplifiers, filters, frequency converters, or demodulators. The signal processing chain has at least two mixers arranged consecutively in the signal processing chain and two numerically controlled oscillators for generating mixing frequencies for frequency conversion of the magnetic resonance signal with the mixers.

In one embodiment of the magnetic resonance scanner, the magnetic resonance scanner is configured to determine a frequency tuning word of the first and/or second numerically controlled oscillator without rounding as a natural number. In other words, the frequencies and divisor factors are selected in such a manner that natural numbers result when calculating the frequency tuning words. Examples of suitable number combinations are shown hereinafter in the description of the figures.

The properties, features and advantages of this disclosure described above and the manner in which these are achieved become clearer and more understandable in connection with the following description of the exemplary embodiments explained in more detail in connection with the drawings.

### BRIEF DESCRIPTION OF THE DRAWINGS

FIG. 1 depicts a diagrammatic view of a magnetic resonance scanner with a local coil according to an example.

FIG. 2 depicts a diagrammatic view of the functional units of a local coil according to an example.

FIG. 3 depicts a diagrammatic view of the functional units of the receiver-side signal processing of a system according to an example.

FIG. 4 depicts a diagrammatic view of a receive path of an embodiment of a system.

FIG. 5 depicts an exemplary signal spectrum after an analog-to-digital conversion of the magnetic resonance signal.

FIG. 6 depicts an exemplary signal spectrum after a frequency conversion.

FIG. 7 depicts an exemplary signal spectrum after a frequency conversion in the baseband.

FIG. 8 depicts an exemplary spectrum of a spectral position of a sampled MR signal at the output of an analog-to-digital converter.

### DETAILED DESCRIPTION

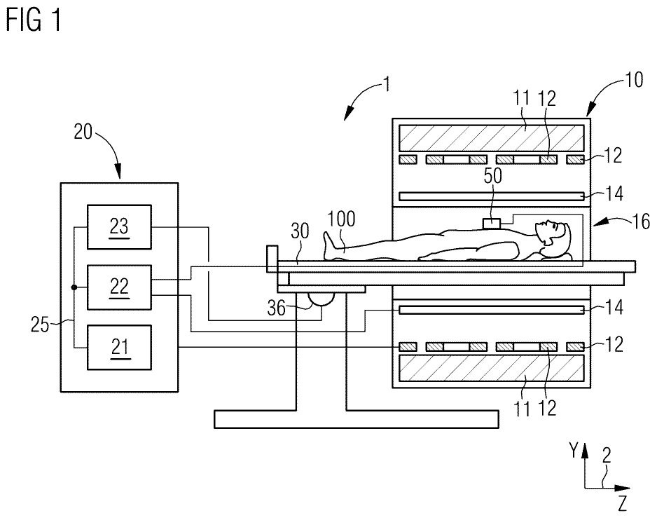

FIG. 1 shows a diagrammatic view of an exemplary embodiment of a magnetic resonance scanner 1 with a local coil 50.

The magnetic resonance scanner 1 has a magnet unit 10 with a field magnet 11 that generates a static magnetic field B0 for the alignment of nuclear spins of samples or a patient 100 in a recording area. The recording area is arranged in a patient tunnel 16 that extends in a longitudinal direction 2 through the magnet unit 10. A patient 100 may be moved into the recording area by the patient table 30 and the positioning unit 36 of the patient table 30. The field magnet 11 may be a superconducting magnet that may provide magnetic fields with a magnetic flux density of up to 3T or even higher in the latest devices.

Furthermore, the magnet unit 10 has gradient coils 12 configured to superimpose variable magnetic fields in three spatial directions on the magnetic field B0 in order to spatially differentiate the detected image areas in the examination volume. The gradient coils 12 may be coils made of normally conducting wires that may generate gradients of the static magnetic field B0 orthogonal to one another in the examination volume.

The magnet unit 10 also has a body coil 14 configured to couple a high-frequency signal supplied via a signal line into the examination volume and to receive resonance signals emitted by the patient 100 and deliver them via a signal line. However, the body coil 14 used for transmitting the high-frequency signal and for reception may be replaced by local coils 50 that are arranged in the patient tunnel 16 close to the patient 100. However, it is also conceivable that the local coil 50 is configured for transmission and reception and a body coil 14 may therefore be omitted.

A control unit 20 supplies the magnet unit 10 with the various signals for the gradient coils 12 and the body coil 14 and evaluates the received signals. A control system 23 coordinates the subunits.

Thus, the control unit 20 has a gradient control 21 configured to supply the gradient coils 12 with variable currents via supply lines, which provide the desired gradient fields in the examination volume in a temporally coordinated manner.

Furthermore, the control unit 20 has a high-frequency unit 22 configured to generate a high-frequency pulse with a predetermined time course, amplitude, and spectral power distribution to excite the magnetic resonance of the nuclear spins in the patient 100. Pulse powers in the kilowatt range may be achieved. The individual units are connected to one another via a signal bus 25.

The high-frequency signal generated by the high-frequency unit 22 is supplied to the body coil 14 via a signal connection and transmitted into the body of the patient 100 in order to excite the nuclear spins there. However, transmission of the high-frequency signal via one or more local coils 50 is also conceivable.

The local coil 50 may receive a magnetic resonance signal from the body of the patient 100 because, on account of the short distance, the signal-to-noise ratio (SNR) of the local coil 50 is better than when receiving with the body coil 14. The MR signal received by the local coil 50 is processed in the local coil 50 and forwarded to the high-frequency unit 22 of the magnetic resonance scanner 1 for evaluation and image capture. The signal connection may be used for this purpose, however wireless transmission, for example, is also conceivable.

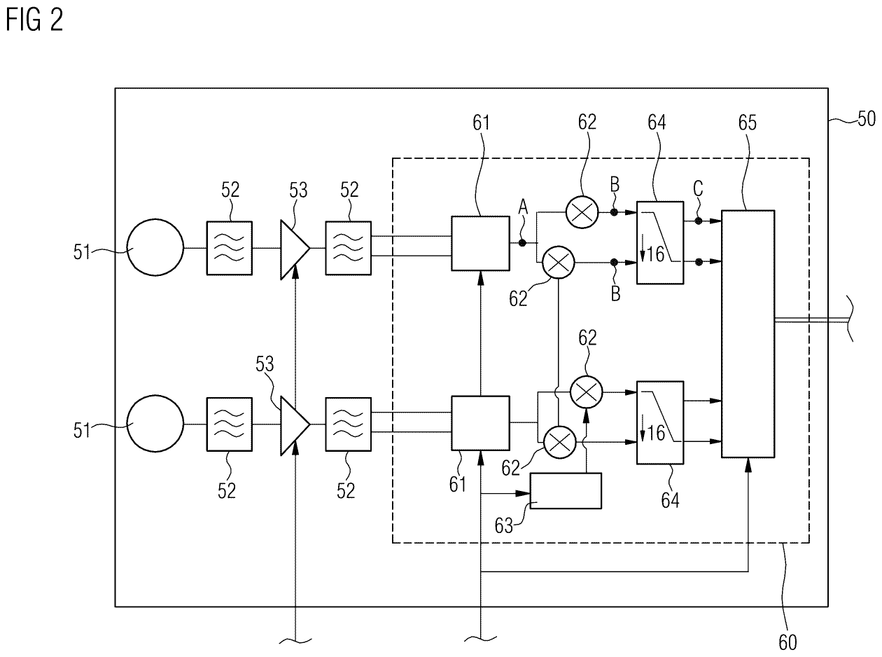

FIG. 2 shows functional units of an embodiment of a local coil in a diagrammatic view. The representation within FIG. 2 is not complete. For example, functions such as detuning have been omitted from the figure for the sake of clarity.

The magnetic resonance signals from the body of the patient are detected by antenna coils 51 and converted into electrical signals. First filters 52 limit the signals passed on to a frequency range of the magnetic resonance signals to be detected, which are defined by the nuclear spins and the magnetic field of the field magnet 11 as the Larmor frequency. The first filter 52 also provides that strong signals from other frequency ranges do not override the subsequent signal path. The first filters 52 may also provide the function of impedance matching for the antenna coil.

Hereinafter, the magnetic resonance signal has its level increased by an amplifier 53 in each signal path. The amplifier 53 may be an amplifier with a low noise figure, which is also referred to as a Low Noise Amplifier (LNA). In an embodiment, the amplifier 53 is switchable in its amplification in order, for example, to detect a magnetic resonance signal at the beginning of the exponential decay without overmodulation and to improve the resolution for weak signals with higher amplification at a later time. Amplification may be adjusted by local control of the local coil or by the control system 23 of the magnetic resonance scanner.

Subsequently, a second filter 52 filters the still analog signal in order to reduce aliasing, i.e., interference from other frequency ranges, during subsequent digitizing.

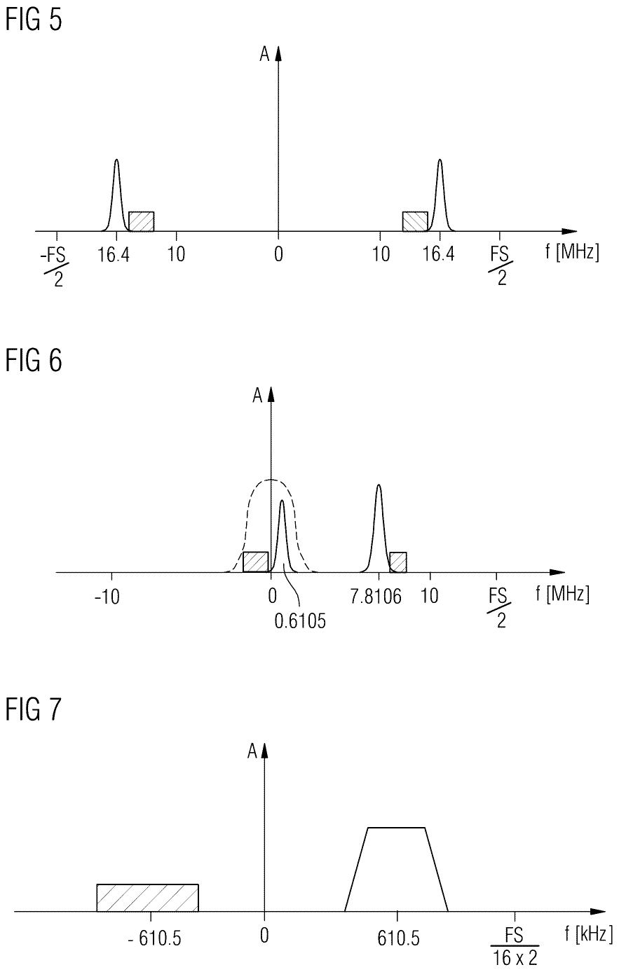

Further, digital signal processing may be performed by an integrated AD converter module 60, such as the ADC 3638 component from Texas Instruments, which is explained hereinafter by way of example. By integrating the different functions in one module or integrated component, costs and energy consumption and thus also the waste heat from the local coil are reduced in an advantageous manner. Miniaturization reduces coupling, but complete shielding of the individual signal processing acts within an integrated component is no longer possible. Therefore, a selection of signal frequencies is necessary in order to prevent coupled signals, such as clock signals or NCO signals, from interfering with the reconstructed images. This is shown in more detail hereinafter in FIG. 5, FIG. 6, and FIG. 7 with different frequency schemes.

In the AD converter module 60, the actual conversion of the analog input signals is first performed by ADC 61 (analog-to-digital converter), which samples the analog signal at a supplied clock frequency and converts it into a digital form.

The clock frequency may be supplied via a signal line or wirelessly from the magnetic resonance scanner 1, or it may be derived locally in the local coil 50 from a signal supplied by a local clock generator. In the case of a wireless local coil 50, it is also conceivable that the local clock generator operates in a free-running manner at least for a predetermined time and is only synchronized at certain intervals.

Further signal processing takes place, for example, in the AD converter module 60 as the generation of so-called IQ signals by mixing the converted real-valued magnetic resonance signal with two digital sine signals that are phase-shifted by 90 degrees relative to one another, or one sine signal and one cosine signal in the digital mixers 62. The mixed signals are provided by a digital IQ oscillator, the so-called Numerically Controlled Oscillator (NCO) 63. Here too, generation may take place as a function of a reference clock of the magnetic resonance scanner 1.

In the AD converter module 60 shown, the data rate is then reduced by a decimation filter 64 before the data is prepared for transmission to the magnetic resonance scanner 1 in a serializer/multiplexer 65. A Hilbert transform may also be performed by a Hilbert filter in order to generate a real signal and thus further reduce the data rate.

FIG. 5 shows an exemplary spectrum of a signal at the measuring point A in FIG. 2 after the ADC 61. The magnetic resonance signal appears in the spectrum as a real signal symmetrical to the zero point. According to the Nyquist theorem, the signal is below half the sampling frequency FS/2.

The signal from the NCO 63 for downmixing the intermediate frequency signal is physically present as a digital switch signal on the ADC DSP chip. The potentially interfering harmonics of this square wave signal extend spectrally far beyond the MR receive signal. The problem therefore remains that the higher-order NCO signal harmonics may couple into the local coil elements or into the ADC input and, due to sampling, potentially fold into the frequency band of the sampled MR signal.

The data rate of the DDC output signal may be reduced via the decimation factor N, which may be selected as a power of two. On the one hand, the Nyquist condition is observed. On the other hand, the harmonics of the data clock signal do not fall into the receive band or alias bands of the sampling and thus result in image artifacts. In the example shown in FIG. 2, N was selected as 16, resulting in an output data rate of 2.5 MS/s.

The NCO frequency is selected in such a manner that the resulting intermediate frequency signal ZF_{dig2} falls in the middle of the first Nyquist band of the DDC output signal.

$$Z {F}_{d i g 2} = \frac{F {S}_{o u t} / 2}{2} = \frac{2.5 MHz / 2}{2} = 0.6 \; 25 MHz$$

This provides that symmetrical distance from 0 Hz and FS/2 (1.25 MHz) remains around the center frequency, as a result of which the requirements for decimation and Hilbert filters are kept as low as possible. This also provides that the NCO signal is spectrally outside the frequency band of the digital MR signal.

The frequency of the appropriate NCO signal is thus given by:

$${F}_{NCO\_initial} = 16.4 MHz - 0.6 \; 25 MHz = 15.775 MHz .$$

However, designing the frequency plan solely according to the criteria specified above results in numerous higher-order harmonics of the NCO signal being folded into the ZF_{dig1} signal frequency band (16.4 MHz+−250 kHz), for example, the 34th signal harmonic (536.35 MHz) falls at 16.350 MHz.

This problem may be circumvented by selecting the NCO frequency in such a manner that it may be represented by multiplication of the Nyquist frequency (FS/2) by a quotient M/N (i.e., a rational number) formed from integers M and N:

$${F}_{N C O} = \frac{M}{N} * \frac{F S}{2}$$

After sampling, the harmonics of this signal fall into a fixed frequency grid of FS/(2*N). The grid spacing has a minimum size so that the sampled MR signal may fit spectrally into the grid without including any of the NCO harmonics:

$$\begin{matrix}\begin{matrix}{F}_{N C O} < Z {F}_{d i g 1} ( normal position ) : & Δ {F}_{norm} > Z {F}_{d i g 1} + \frac{B W}{2} - {F}_{N C O}\end{matrix} \\ \begin{matrix}{F}_{N C O} > Z {F}_{d i g 1} ( inverted position ) : & Δ {F}_{i n v e r t e d} > {F}_{N C O} + \frac{B W}{2} - Z {F}_{d i g 1}\end{matrix}\end{matrix}$$

From this, a maximum value for the selection of the parameter N may be calculated:

$${N}_{max} = ROUNDING DOWN ( \frac{FS / 2}{Δ F} )$$

For larger N, either a harmonic folds into the ZF_{dig1} band, or the frequency deviation from the optimal NCO frequency becomes too large.

M is calculated as:

$$M = ROUNDING ( \frac{N * {F}_{NCO\_initial}}{FS / 2} )$$

By experimentally inserting integers into N, up to Nₘₐₓ, the quotient M/N may be determined, which results in an NCO frequency with the smallest distance from F_{NCO_initial}. In the example shown in FIG. 5 (control position), the optimum NCO frequency is produced with N=19 according to:

$${F}_{NCO\_opt} = \frac{15}{19} * \frac{40 MHz}{2} = 15.7 \; 8947 … MHz$$

The deviation from F_{NCO_initial} is 14.5 kHz, or approx. 0.09%, which is tolerably low in view of the spectral position of the resulting ZF_{dig2}. The grid spacing is:

$$Δ F = \frac{F S}{2 * N} = 1.0 \; 526 … MHz$$

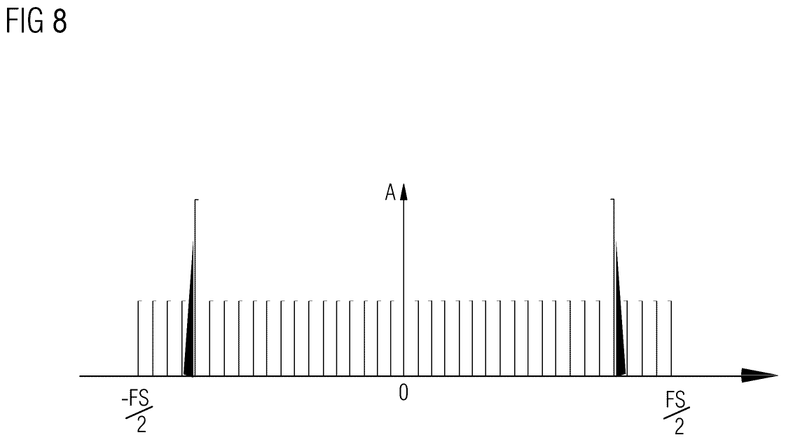

FIG. 8 shows the spectral position of the sampled MR signal ZF_{dig1} at the output of the ADCs and the frequency grid created by folded NCO signal harmonics for the present example. The spectrum of the real ZF_{dig1} signal fits into the grid without including any of the spectral lines.

An NCO signal with the resulting frequency F_{NCO_opt} cannot be generated precisely with an NCO of finite resolution. A frequency deviation remains due to the necessary rounding of the Frequency Tuning Word (FTW):

$$FTW = ROUNDING ( \frac{{2}^{n} * {F}_{N C O}}{F S} )$$

In the example shown, when using an NCO FTW resolution of 32 bits specified by the AD converter module 60 and an NCO clock frequency of 40 MHz, a frequency error of approx. −3.4 mHz occurs. The spectral position of the folded NCO signal harmonics is fanned out with increasing harmonic order as a result. However, due to the negligible size of the frequency error, no interfering folds are to be expected.

After data reduction by the decimator 64, the resulting ZF_{dig2} signal is converted into a serial data stream in a serializer 65 and transferred from the AD converter module 60 to the subsequent function blocks via, for example, an LVDS interface. This may be followed by a Hilbert filter 72 implemented in an ASIC or FPGA, in which the desired sideband of the mixture (here, the upper sideband) is selected and the mirror band is suppressed by frequency-independent relative phase shifting of the IQ signal components and subsequent correct sign addition of the two components of the resulting analytical signal. A real-valued signal with 1×2.5 MS/s appears at the output of the summing element 73, which may then be transmitted in the serializer 74 as a serial data signal via a cable or an optical fiber. In particular, wireless transmission of the digital signal by a transmitter 54 and a receiver 55 operating in a GHz-ISM band, for example, is also conceivable.

At the receiving end in the magnetic resonance scanner 1, RX signal processing is performed as in a known IQ receiver before the magnetic resonance signals are provided for further processing, for example, image reconstruction.

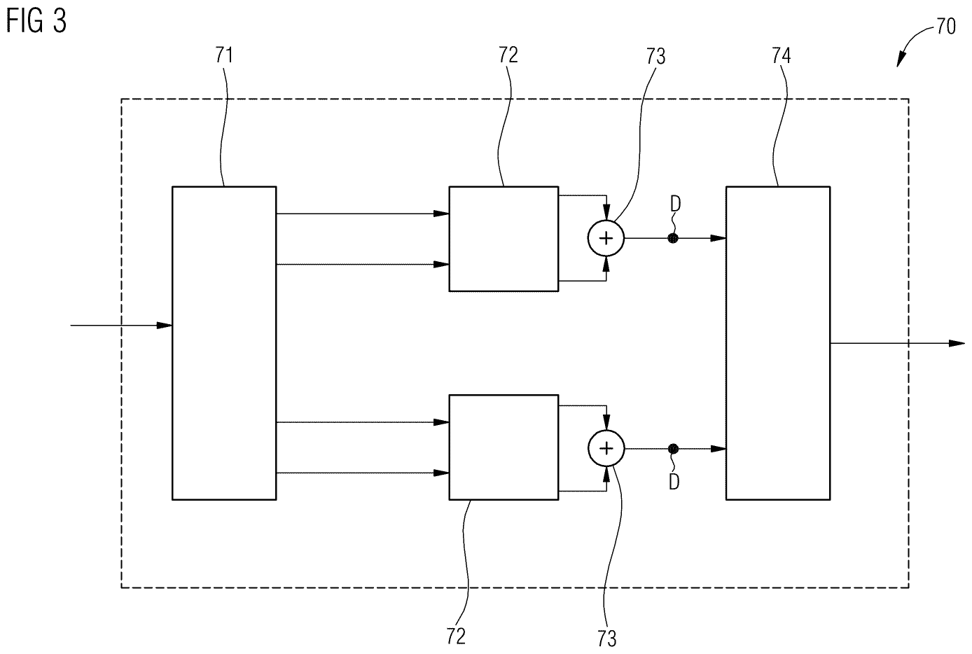

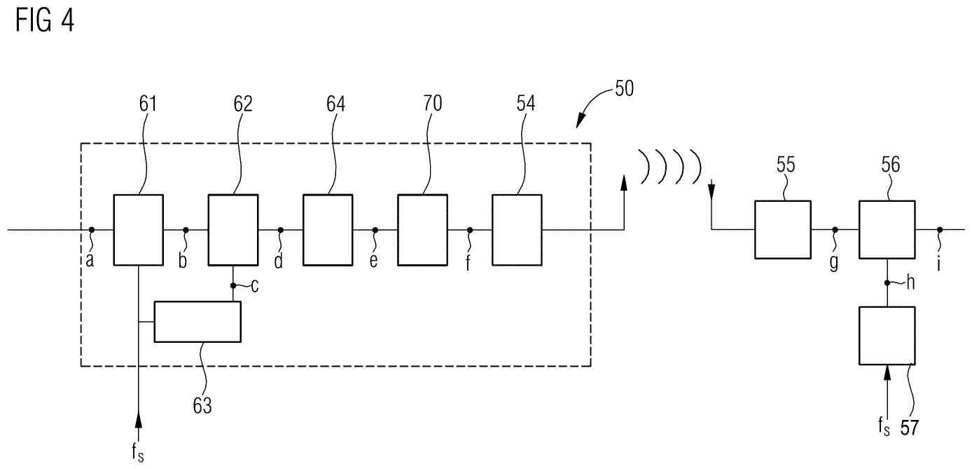

FIG. 4 shows an embodiment in which the complex IQ signal is subjected to a Hilbert transform 72 in a sideband filter 70 before transmission to the MR system, see FIG. 3 for details of the sideband filter 70. Subsequently, by specifying the signs for the following addition 73 of the Hilbert filter output signals, a selection is made regarding whether signals from the negative frequency range, or signals from the positive frequency range of the complex Hilbert filter input signal are reused. The real-valued output signal requires only half the bandwidth compared to the complex-valued input signal. Accordingly, the data rate is reduced by a factor of 0.5.

FIG. 3 shows an example of such a sideband filter 70 in an implementation with a Hilbert filter. The implementation may be carried out, for example, by an FPGA module. First, the data streams of the I and Q signals are separated again using a demultiplexer 71 and then fed to the Hilbert transformers 72, each of which performs a frequency-independent relative phase shift of 90° between the imaginary part and the real part. The two components of the Hilbert filter output signal are then added in a summing element 73 so that, depending on the signs selected, the sideband, which was created during mixing and does not contain any MR information, is eliminated.

However, without countermeasures, on account of the rounding error in the frequency setting of the NCO 63 involved in frequency conversion, and thus the low NCO frequency deviation of 3.4 MHz, the rigid phase coupling between the MRI transmit and receive system would be lost as in practice send and receive signals may no longer be mixed at identical intermediate frequencies.

FIG. 4 shows an exemplary receive chain of a system with a local coil 50. For a better overview, not all individual elements of the preceding figures are repeated. To achieve rigid phase coupling, the system provides a compensation apparatus, which has a frequency converter 56 and a second numerically controlled oscillator NCO2 57. FIG. 4 also provides an overview of the signal processing stages shown in FIG. 2 in order to illustrate the relationships between the frequencies used.

Here, two different exemplary frequency schemes are considered, for which the individual frequencies at the individual reference points a to i in FIG. 4 are specified. The only common factor here is the input frequency of the magnetic resonance signal, for example 63.600 MHz for a magnetic resonance scanner for 1.5 T.

After AD conversion in the ADC 61 with a sampling frequency fs, the magnetic resonance signal at point b is converted into a digital real magnetic resonance signal. FIG. 5 shows a diagrammatic view of the spectrum at point b of FIG. 4. However, the bandwidths of the individual signals are not shown to scale but have been broadened for clarification. The signal at +/−16.4 MHz is the magnetic resonance signal converted by undersampling, while the hatched block indicates the noise floor converted by undersampling, which appears in the mirror frequency band of the subsequent mixing.

The mixer 62 mixes the magnetic resonance signal with the first mixed signal of the NCO 63 (point c) at a frequency F_{NCO1}. After the mixer 62 and the decimator 64, the magnetic resonance signal converted in the frequency range is available at point d in the form of a complex-valued IQ intermediate frequency signal.

FIG. 6 shows an exemplary spectrum after mixing at point d for the frequencies specified in FIG. 5. The magnetic resonance signal is located at the positive frequency 0.6105 MHz, while the noise band containing no information is located in the negative frequency range. The transfer function of the following decimation filter is indicated. The other product of the mixing folds into the frequency range around 7 MHz, i.e., into the stopband of the following decimation filter. FIG. 7 shows the two signals around the zero frequency point in detail again, with the noise-induced signal without MR information in the negative range and the magnetic resonance signal around the positive frequency 610.5 kHz.

Hereinafter, the MR signal present in the form of an IQ signal at point d is converted into a real-valued signal at point f with the aid of a Hilbert filter and adder integrated into the sideband filter 70. As already described in FIG. 3, a sideband is suppressed or canceled, in this case the sideband in the negative frequency range with a noise-induced signal without MR information.

The real-valued signal is then transmitted from the transmitter 54 to the receiver 55 of the magnetic resonance scanner 1, which is then also present at point g.

Here, mixing takes place with the frequency converter 56 using a complex-valued mixed signal from the NCO2 57 (point h), the magnetic resonance signal being available at point i for further processing or image reconstruction.

If the frequency of the NCO2 signal corresponds exactly to the frequency of the NCO1 signal, the ZF_{dig2} signal in the frequency converter 56 may be exactly converted back to the ZF_{dig1} frequency. To this end, the NCO2 57 is programmed with the same FTW as the NCO1 63 and is timed with the same clock frequency (40 MHz). Viewed from point b to point i along the signal path, the manipulations of the spectral signal position therefore remain transparent. The NCO1 63 FTW resolution is specified for the off-the-shelf AD converter module 60 and cannot be altered there. On the system side, the NCO2 57 may be implemented in an FPGA, for example, which offers an FTW resolution of 64 bits, for example. This enables a 16.4000 MHz NCO signal to be generated precisely, which is then used in a further frequency converter to convert the ZF_{dig2} signal symmetrically around 0 Hz into the complex-valued baseband. Alternatively, the high resolution may already be used in the NCO2 57 to convert the ZF_{dig2} signal directly into the complex-valued baseband in the frequency converter 56.

In the following table, the signal frequencies are listed at the reference points for two different scenarios:

| | Scenario 1 | | Scenario 2 | |
|---|---|---|---|---|
| a | 63.600 | MHz | 63.600 | MHz |
| b | 16.400 | MHz | 3.600 | MHz |
| c | 1695381827 *fₛ/(2\hat{ }32) | | 920350135 *fₛ/(2\hat{ }32) | |
| d | | | | |
| e | ~610.526319 kHz @ 2.5 MS/s (complex) | | ~685.714286 kHz @ 2.5 MS/s (complex) | |
| f | ~610.526319 kHz @ 2.5 MS/s (real) | | ~685.714286 kHz @ 2.5 MS/s (real) | |
| g | ~610.526319 kHz @ 40 MS/s (real) | | ~685.714286 kHz @ 20 MS/s (real) | |
| h | 1695381827 *fₛ/(2\hat{ }32) MHz | | 920350135 *fₛ/(2\hat{ }32) | |
| i | 16.400 MHz @ 40 MS/s (real) | | 3.600 MHz @ 10 MS/s (real) | |
| fₛ | 40 | MHz | 20 | MHz |

While scenario 1 corresponds to the frequencies already discussed and calculated in connection with FIG. 5, scenario 2 corresponds to the following parameters:

$$F S = 20 MS / s$$

$$N = 8 ( DDC Decimation Factor )$$

$$F {S}_{D D C} = \frac{F S}{N} = 2.5 MHz ( DDC Output Sampling Frquency )$$

$$Z {F}_{d i g 1} = 3.6 \; 00 MHz$$

$$\begin{matrix}{F}_{NCO\_initial} = Z {F}_{d i g 1} + \frac{F {S}_{D D C}}{4} = 3.6 MHz + \frac{2.5 MHz}{4} \\ = 4.225 MHz ( inverted position )\end{matrix}$$

$${F}_{N C O} > Z {F}_{d i g 1} ( inverted position ) :$$

$$Δ {F}_{i n v e r t e d} > {F}_{N C O} + \frac{B W}{2} - Z {F}_{d i g 1} = 4.2 \; 25 MHz + 0.35 MHz - 3.6 MHz = 0.975 MHz$$

$${N}_{max} = ROUNDING DOWN ( \frac{FS / 2}{Δ F} ) = ROUNDING DOWN ( \frac{20 MHz / 2}{0.9 \; 75 MHz} ) = 20$$

$${N}_{o p t} = 7 ( determined by trial and error )$$

$$M = ROUNDING ( \frac{{N}_{o p t} * {F}_{NCO\_initial}}{FS / 2} ) = ROUNDING ( \frac{7 * 4.2 \; 25 MHz}{10 MHz} ) = 3$$

$${F}_{NCO\_opt} = \frac{M}{{N}_{o p t}} * \frac{F S}{2} = \frac{3}{7} * \frac{20 MHz}{2} = 4.2857142 \; 8571 … MHz$$

$$FTW = ROUNDING ( \frac{{2}^{32} * 4.28571428571}{20} ) = 920350135$$

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A local coil for a magnetic resonance scanner, the local coil comprising:
an analog-digital converter;
a digital mixer;
an oscillator; and
a data rate decimator,
wherein the digital mixer and the oscillator are configured to convert a digitized magnetic resonance (MR) signal in a frequency position such that the MR signal is converted spectrally centrally into a frequency range that corresponds either to a positive frequency subrange or a negative frequency subrange of a baseband at an output of the data rate decimator.

2. The local coil of claim 1, wherein the digital mixer is a semi-complex mixer.

3. The local coil of claim 1, wherein the oscillator is an in-phase/quadrature (IQ) numerically controlled oscillator.

4. The local coil of claim 1, wherein the oscillator is configured to generate a frequency of an oscillator signal outside a frequency range of a sampled MR signal.

5. The local coil of claim 1, wherein the oscillator is configured to generate an oscillator signal with a frequency such that a spectrum of a sampled MR signal falls between two adjacent alias products of the oscillator signal.

6. The local coil of claim 5, wherein the frequency of the oscillator signal is configured to be selected such that the frequency of the oscillator signal is represented by multiplying a Nyquist frequency by a quotient M/N, wherein M and N are integers.

7. The local coil of claim 1, wherein a frequency of an oscillator signal is configured to be selected such that the frequency of the oscillator signal is represented by multiplying a Nyquist frequency by a quotient M/N, wherein M and N are integers.

8. The local coil of claim 1, wherein the digital mixer and the analog-to-digital converter are monolithic in design.

9. The local coil of claim 1, further comprising:
a wireless transmission apparatus configured to wirelessly transmit a downmixed digital MR signal to the magnetic resonance scanner.

10. A system comprising:
a magnetic resonance system comprising a magnetic resonance scanner; and
a local coil comprising an analog-digital converter, a digital mixer, an oscillator, and a data rate decimator,
wherein the local coil is configured to receive a reference signal from the magnetic resonance scanner of the magnetic resonance system via a signal connection,
wherein the oscillator is configured to generate a mixing frequency for the digital mixer as a function of the reference signal,
wherein the digital mixer and the oscillator are configured to convert a digitized magnetic resonance (MR) signal in a frequency position such that the MR signal is converted spectrally centrally into a frequency range that corresponds either to a positive frequency subrange or a negative frequency subrange of a baseband at an output of the data rate decimator.

11. The system of claim 10, wherein a signal processing chain for magnetic resonance signals has at least two mixers and two numerically controlled oscillators for generating mixing frequencies for frequency conversion of the MR signal,
wherein the system is configured to perform the frequency conversion of the MR signal in the signal processing chain, which corresponds to a mixture of the MR signal with a virtual mixed signal, and
wherein a quotient of a frequency of the virtual mixed signal and a frequency of the reference signal indicates a rational number.

12. The system of claim 11, wherein the quotient of the frequency of the virtual mixed signal and the frequency of the reference signal indicates a natural number.

13. The system of claim 12, wherein the numerically controlled oscillators are adjusted in such a manner that frequency conversion by a first mixer of the at least two mixers in the signal chain is compensated by frequency conversion by a second mixer of the at least two mixers, so that the frequency of a signal before the first mixer is equal to the frequency of a signal after the second mixer.
